(19) United States
(12) Patent Application Publication
(10) Pub. No.: US 2026/0118454 A1
(43) Pub. Date: Apr. 30, 2026

(54) PHYSICAL QUANTITY DETECTION DEVICE, METHOD OF CONTROLLING PHYSICAL QUANTITY DETECTION DEVICE, AND COMPUTER-READABLE RECORDING MEDIUM STORING INSTRUCTIONS FOR CONTROLLING PHYSICAL QUANTITY DETECTION DEVICE

(71) Applicant: KABUSHIKI KAISHA TOYOTA CHUO KENKYUSHO, Nagakute-shi (JP)

(72) Inventor: Kosuke TAHARA, Nagakute-shi (JP)

(73) Assignee: KABUSHIKI KAISHA TOYOTA CHUO KENKYUSHO, Nagakute-shi (JP)

(21) Appl. No.: 19/333,509

(22) Filed: Sep. 19, 2025

(30) Foreign Application Priority Data
Oct. 25, 2024 (JP) 2024-188436

(51) Int. Cl. G01R 33/26

(52) U.S. Cl. CPC G01R 33/26

(57) ABSTRACT

A physical quantity detection device may comprise: a sensor element including an emission center; an excitation light pulse generator configured to generate excitation light and irradiate the excitation light to the sensor element; a high frequency pulse generator configured to generate a high frequency pulse for controlling a spin qubit of the emission center and irradiate the high frequency pulse to the sensor element; and a light detector configured to detect light emission from the emission center. The emission center may have two spin qubits that differ from each other. The two spin qubits may be equivalent to each other and may have different levels from each other. The high frequency pulse generator may generate the high frequency pulse in which two different frequencies are superimposed and may irradiate the high frequency pulse to the sensor element to simultaneously perform control on the two spin qubits.

### REFERENCE TO RELATED APPLICATIONS

This application claims priority from Japanese Patent Application No. 2024-188436 filed on Oct. 25, 2024. The entire content of the priority application is incorporated herein by reference.

### BACKGROUND ART

The description herein relates to a physical quantity detection device, a method of controlling the physical quantity detection device, and a computer-readable recording medium storing instructions for controlling the physical quantity detection device.

Conventionally, physical quantity detection devices that use sensor elements with spin defects (emission centers) in solids to detect physical quantities such as magnetics, temperatures, and electric fields have been proposed. Such a physical quantity detection device utilizes changes that occur in a light emission intensity of the emission center according to the physical quantity. Specifically, excitation energy and a resonant electromagnetic wave are given to the sensor element, and the change in the light emission intensity that occurs upon ground level- or excitation level-resonance of the emission center is detected. A related technology is described in WO2023/136015.

### DESCRIPTION

An emission center that includes two spin qubits that differ from each other (an emission center having four or more magnetic quantum numbers) is known. For example, silicon vacancy in silicon carbide, which is a spin 3/2 system, may be exemplified. However, compared to an NV center (nitrogen-vacancy center) of a diamond having similar qubits, a signal strength (contrast) is problematically small.

One technique disclosed in the present application is a physical quantity detection device. The physical quantity detection device may comprise: a sensor element including an emission center; an excitation light pulse generator configured to generate excitation light and irradiate the excitation light to the sensor element; a high frequency pulse generator configured to generate a high frequency pulse for controlling a spin qubit of the emission center and irradiate the high frequency pulse to the sensor element; and a light detector configured to detect light emission from the emission center. The emission center may have two spin qubits that differ from each other. The two spin qubits may be equivalent to each other and may have different levels from each other. The high frequency pulse generator may generate the high frequency pulse in which two different frequencies are superimposed and may irradiate the high frequency pulse to the sensor element to simultaneously perform control on the two spin qubits.

When an emission center with two spin qubits is irradiated with a high frequency pulse that has only one frequency, only one spin qubit can be controlled. Since the other spin qubit, which is not controlled, does not contribute to any detection signal, a detection signal can only be obtained from one of the two spin qubits. According to the above structure, the two spin qubits can be controlled simultaneously by irradiating the high frequency pulse in which two different frequencies are superimposed. Due to this, detection signals can be acquired from both of the two spin qubits. Since a detection intensity (contrast) can be increased, detection sensitivity of the physical quantity detection device can be improved.

### BRIEF DESCRIPTION OF THE DRAWINGS

FIG. 1 shows a schematic diagram of a physical quantity detection system.

FIG. 2 is an energy level diagram of a silicon vacancy.

FIG. 3 shows changes in an energy level of a spin.

FIG. 4 is a flowchart of a physical quantity detection sequence.

FIG. 5 shows a timing chart for applications of excitation light pulse EP and high frequency pulse HP.

FIG. 6 shows quantum states represented by Bloch spheres.

FIG. 7 is a flowchart of π/2 pulse width calibration.

FIG. 8 shows an example of a continuous wave ODMR spectrum.

FIG. 9 shows an example of a Rabi oscillation.

FIG. 10 illustrates a detection principle in a comparative example.

FIG. 11 illustrates a detection principle according to an embodiment disclosed herein.

FIG. 12 shows quantum states in a second embodiment.

FIG. 13 is a timing chart for applications of excitation light pulse EP and high frequency pulse HP in a third embodiment.

FIG. 14 shows an example of results of a sensor operation with an AC magnetic field AF application.

### DETAILED DESCRIPTION

### First Embodiment

### (Overview of Physical Quantity Detection Device 1)

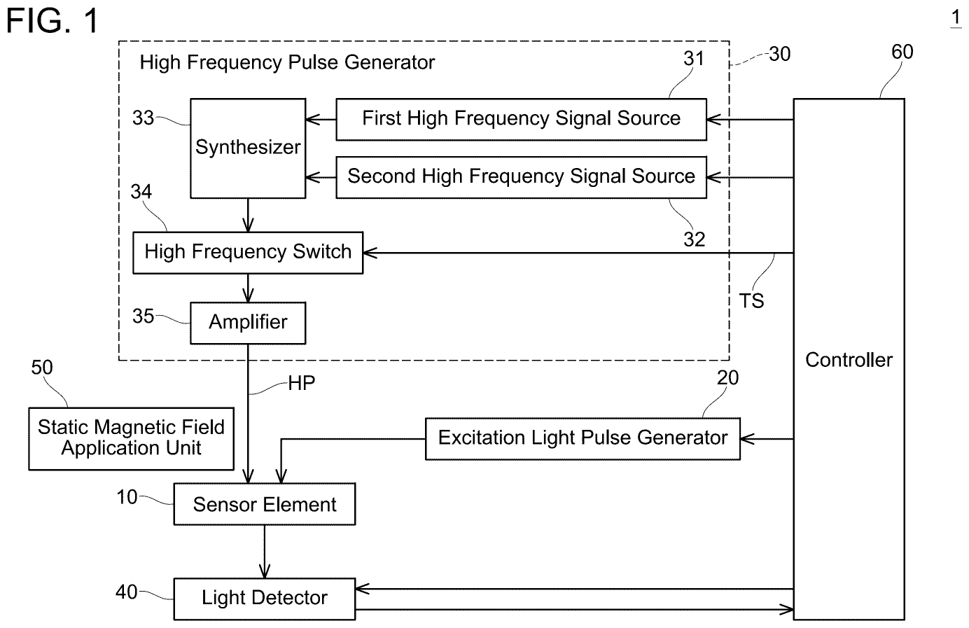

FIG. 1 schematically shows a schematic configuration of a physical quantity detection device 1 according to a first embodiment. The physical quantity detection device 1 mainly comprises a sensor element 10, an excitation light pulse generator 20, a high frequency pulse generator 30, a light detector 40, a static magnetic field application unit 50, and a controller 60.

The sensor element 10 is configured of a material containing an emission center. The emission center has two spin qubits that are different from each other. Further, the two spin qubits are equivalent to each other and are configured of different levels. In this example, the emission center has a spin 3/2 that is photo-detectable and magnetic resonance-detectable in silicon carbide (SiC). Specifically, material of the sensor element 10 is 4H-SiC, and the emission center is a silicon vacancy. The sensor element 10 may be attached to a tip of a sensor probe that is not shown.

The static magnetic field application unit 50 is configured to apply a known static magnetic field to the sensor element 10. The static magnetic field application unit 50 is disposed in the vicinity of the sensor element 10. The static magnetic field application unit 50 may be, for example, a permanent magnet or an electromagnet. The light detector 40 is a unit configured to detect light emission of the emission center. The light detector 40 may comprise light detector such as a photodiode, filter, mirror, lens, or the like.

The excitation light pulse generator 20 is a unit configured to generate an excitation light pulse EP and irradiates the same to sensor element 10. The excitation light pulse generator 20 may be equipped with a light source such as a light emitting diode, a filter, a mirror, a lens, etc. Further, since the excitation light pulse EP is irradiated as a digital pulse, the excitation light pulse generator 20 may comprise an acousto-optic modulator or the like for digital modulation as needed. Alternatively, the light source itself may be configured capable of being digitally modulated.

The high frequency pulse generator 30 is a unit configured to generate a high frequency pulse HP to control a spin qubit of the emission center and irradiate the same to the sensor element 10. The high frequency pulse generator 30 in the present embodiment comprises a feature of generating a high frequency signal with two different frequencies superimposed as a synchronized high frequency pulse HP. Due to this, two spin qubits can be controlled simultaneously as described below.

The high frequency pulse generator 30 mainly comprises a first high frequency signal source 31, a second high frequency signal source 32, a synthesizer 33, a high frequency switch 34, and an amplifier 35. The first high frequency signal source 31 is a unit configured to generate a high frequency signal of a first resonance frequency f₊. The second high frequency signal source 32 is a unit configured to generate a high frequency signal of a second resonance frequency f₋. As described below, the first resonance frequency f₊ is a resonance frequency of magnetic quantum numbers +1/2 and +3/2. The second resonance frequency f₋ is a resonance frequency of magnetic quantum numbers −1/2 and −3/2. The synthesizer 33 is a unit configured to synthesize an output from the first high frequency signal source 31 and an output from the second high frequency signal source 32. A timing signal TS is input to the high frequency switch 34 from the controller 60. The high frequency switch 34 pulses the high frequency signal based on the timing signal TS. The amplifier 35 is a unit configured to output an amplified high frequency pulse HP. If necessary, the high frequency pulse generator 30 may comprise a high frequency circuit element (e.g., antenna, waveguide, etc.) to irradiate pulses the sensor probe.

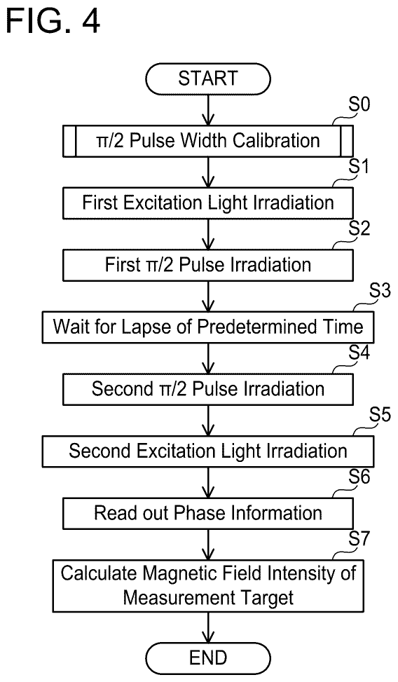

The controller 60 is a unit configured to control operations of the excitation light pulse generator 20, the high frequency pulse generator 30, the photodetector 40, and the like. For example, various information terminal devices such as known general-purpose computers can be used for the controller 60. The controller 60 mainly comprises a memory and an arithmetic circuit that are not shown. The memory mainly stores a physical quantity detection program. The arithmetic circuit is configured of a microprocessor equipped with an NPU, GPU, etc. The arithmetic circuit is configured to perform a physical quantity detection sequence (FIG. 4) described below by executing the physical quantity detection program stored in the memory.

### (Principle of Operation)

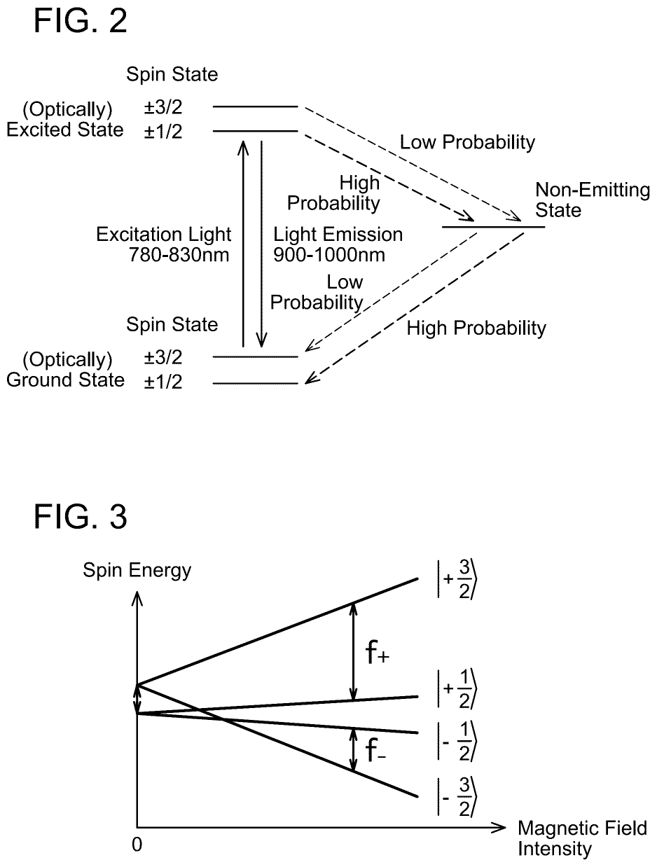

Principle of operation will be described. FIG. 2 shows an energy level diagram of a silicon vacancy. Its main (optical) energy level has a ground state and an excited state. Emission of light (photoluminescence, fluorescence) from the silicon vacancy is observed when it is irradiated with light above this energy difference. Typical excitation light wavelengths are around 780 to 830 nm. Further, an emission spectrum is about 900 to 1000 nm at a room temperature. A closer look at the energy structure of the ground and excited states reveals a presence of electron spin-derived levels. Silicon vacancy is of a spin 3/2 system, and is configured of four levels with magnetic quantum numbers m=+3/2, +1/2, −1/2, and −3/2. If an external magnetic field is absent, +3/2, −3/2 and +1/2, −1/2 each have the same energy (degenerate). As such, in FIG. 2, they are illustrated collectively as ±3/2 and ±1/2.

With the silicon vacancy, there is a transition process from the excited state to the ground state through a non-emitting state. If the transition takes place through the non-emitting state, no light emission occurs at 900 to 1000 nm. A probability of this non-emission process occurring is spin-state dependent, and becomes higher in case of m=±1/2 rather than in case of m=±3/2. Thus, by repeating processes of excitation and relaxation with photoexcitation for a certain period of time, it is possible to form a state in which the magnetic quantum number is biased to m=±1/2 ((1) spin polarization by light).

Furthermore, a difference in transition probability to the non-emitting state indicates that “the emission intensity increases when the spin is at m=±3/2 compared to when the spin is at m=±1/2” ((2) optical readout of spin state).

Spin energy is affected by external fields such as magnetic and electric fields, as well as lattice distortion. Since its response to the magnetic field is the most prominent, the magnetic field will be exemplified hereinbelow. FIG. 3 shows changes in energy levels of spin when a magnetic field parallel to a c-axis is applied to a 4H-SiC crystal. When degeneracy at zero magnetic field is resolved, four different energies appear. Here, the first resonance frequency f₊ is a resonance frequency equal to an energy difference between m=+3/2 and +1/2. Further, the second resonance frequency f₋ is a resonance frequency equal to an energy difference between m=−3/2, −1/2. By applying high frequency waves with the first resonance frequency f₊ and the second resonance frequency f₋, inter-state occupancy probability can be changed ((3) spin state control by magnetic resonance).

By detecting minute changes in energy levels using (1) spin polarization (initialization) by light, (3) spin state control by magnetic resonance, and (2) optical readout of spin state, as explained above, minute physical quantities (such as magnetic fields) can be detected. Specific sequences will described below.

### (Sequence of Physical Quantity Detection)

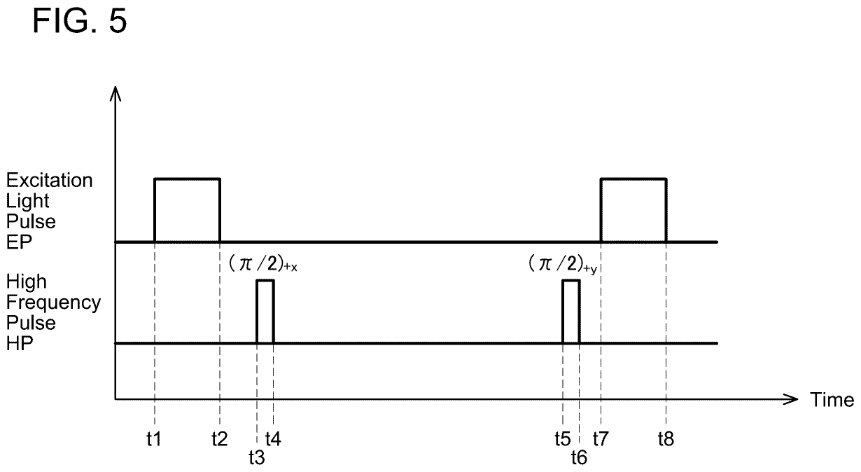

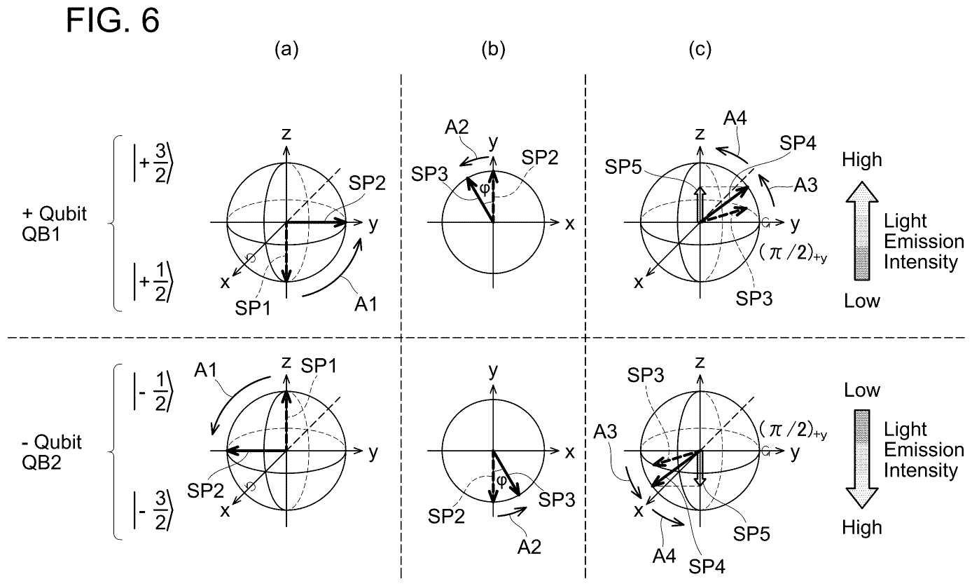

FIG. 4 shows a flowchart of a sequence of a physical quantity detection. In the present embodiment, a case of detecting a physical quantity that does not undergo change over time (DC magnetic field) will be described. FIG. 5 also shows a timing chart for applications of excitation light pulse EP and high frequency pulse HP. Further, FIG. 6 shows diagrams of quantum states represented by Bloch spheres. An upper part of FIG. 6 shows quantum states of a + qubit QB1, and a lower part shows quantum states of a − qubit QB2. FIG. 6 (a) to (c) also show quantum states at respective stages described below.

In step S0, π/2 pulse width calibration is performed. A specific calibration method will be described later.

In step S1, a first excitation light irradiation is performed. Specifically, the excitation light pulse EP is irradiated to the sensor element 10 using the excitation light pulse generator 20 (see FIG. 5, time t1 to t2). Due to this, electron spin is initialized to a state of m=±1/2. As shown in FIG. 6(a), the initialized electron spin SP1 is aligned along a z-axis (quantization axis).

In step S2, a first π/2 pulse irradiation is performed. Specifically, the high frequency pulse HP of π/2 pulse is irradiated to the sensor element 10 using the high frequency pulse generator 30 (see FIG. 5, time t3 to t4). The π/2 pulse is given a high frequency as a pulse for a certain length of time. Since the π/2 pulse is well known, the details thereof will be omitted.

Here, the disclosure herein is characterized by simultaneous application of a π/2 pulse of the first resonance frequency f₊ and a π/2 pulse of the second resonance frequency f₋. That is, it is characteristic in that two sets of + qubit QB1 and − qubit QB2 can be controlled simultaneously. Due to this, a superposition state in which m=+1/2, +3/2, and m=−1/2, −3/2 are each occupied at half probability can be created.

Further, a phase of the first π/2 pulse irradiation is set to +x. Due to this, as shown in the quantum state by the Bloch sphere in FIG. 6(a), the quantum state can be controlled to rotate 90 degrees in a direction of positive rotation about an x-axis. Due to this, an electron spin SP1 along the quantization axis (z-axis) is tilted to an xy-plane perpendicular to the quantization axis, and thus becomes an electron spin SP2 (see arrow A1).

In step S3, the process waits for a predetermined time to elapse after the first π/2 pulse irradiation (see FIG. 5, time t4 to t5). During this standby, information on the physical quantity (magnetic field) is accumulated in the phase difference of the quantum state. In the representation of the quantum state in FIG. 6(b), the electron spin SP2 is inverted on the xy-plane, and acquires a phase during the predetermined time by interaction with the magnetic field being the measurement target, and becomes an electron spin SP3. Here, if the measurement target is a magnetic field (first embodiment, FIG. 6), a sign of the phase φ is identical between the + qubit Q B1 and the − qubit QB2. As such, the electron spin SP3 rotates in the same direction (see FIG. 6 (b), arrow A2; illustrated herein counterclockwise).

In step S4, a second π/2 pulse irradiation is performed. Specifically, the π/2 pulse of the high frequency pulse HP is irradiated to the sensor element 10 using the high frequency pulse generator 30 (see FIG. 5, time t5 to t6). Due to this, control for converting the phase difference into occupancy probability for the two sets of the + qubit QB1 and the − qubit QB2 can be performed.

Specifically, a phase of the second π/2 pulse irradiation is set to +y. In other words, the phase of the π/2 pulse of the first resonance frequency f₊ and the phase of the π/2 pulse of the second resonance frequency f₋ are made identical to each other (+y). Due to this, the rotation direction of the quantum states of the +qubit QB1 and the −qubit QB2 can be set to the same direction. Thus, as shown in FIG. 6 (c), the quantum states of the +qubit QB1 and the −qubit QB2 can be rotated 90 degrees in the direction of positive rotation about the y axis. As a result, an electron spin SP4 is obtained (see arrow A3).

Here, as shown in FIG. 6(c), for the + qubit QB1, the emission intensity is higher in the +z-axis direction and lower in the −z-axis direction. On the other hand, for the − qubit QB2, the light emission intensity is higher in the −z-axis direction and lower in the +z-axis direction. Further, with the + qubit QB1, a z-axis component of the electron spin SP4 becomes positive (emission intensity becomes higher) by rotating the quantum state 90 degrees in the direction of positive rotation of the y-axis. With the − qubit QB2, by rotating the quantum state by 90 degrees in the direction of positive rotation of the y-axis, the z-axis component of electron spin SP4 becomes negative (emission intensity becomes higher). In other words, since the emission intensity can be increased for both the +qubit QB1 and the −qubit QB2, the sensor sensitivity can thus be increased as described below.

In step S5, a second excitation light irradiation is performed. Specifically, the excitation light pulse EP is irradiated to the sensor element 10 using the excitation light pulse generator 20 (see FIG. 5, time t7 to t8). As a result, the electron spin is projected onto the z-axis (quantization axis) to become an electron spin SP5 along the z-axis (see arrow A4). That is, the electron spin SP5 is a z-axis component of the electron spin SP4. The light emission intensity of the emission center corresponds to a z-component of the electron spin SP5.

In step S6, phase information is read out. Specifically, the emission state of the emission center is detected by the photodetector 40 in a state of being given the excitation light pulse EP. Step S5 and step S6 are performed simultaneously. For convenience, steps S5 and S6 may be separated in the present specification.

In step S7, an intensity of the magnetic field being the measurement target is calculated. Specifically, the phase information of the electron spin SP5 state detected by the photodetector 40 is a state corresponding to the DC magnetic field of the measurement target. By appropriately processing this phase information, the intensity of the DC magnetic field can be calculated.

In this example technique, in the first π/2 pulse irradiation (step S2), the phase is set to x (i.e., rotated 90 degrees about the x-axis). On the other hand, in the second π/2 pulse irradiation (step S4), the phase is set to y (i.e., rotated 90 degrees about the y-axis). The reason thereof will be explained. In the second π/2 pulse irradiation, when the phase is set to x, a readout signal of the phase information (z-coordinate of the electron spin SP5) becomes a cosine function. On the other hand, when the phase is set to y in the second π/2 pulse irradiation, the readout signal of the phase information becomes a sine function. Here, since the change in phase φ is minute, the rate of change (differential coefficient) can be larger for the sine function than for the cosine function. Therefore, in the second π/2 pulse irradiation (step S4), by setting the phase to y, the detection sensitivity of the minute signal can be increased.

### (π/2 Pulse Width Calibration Sequence)

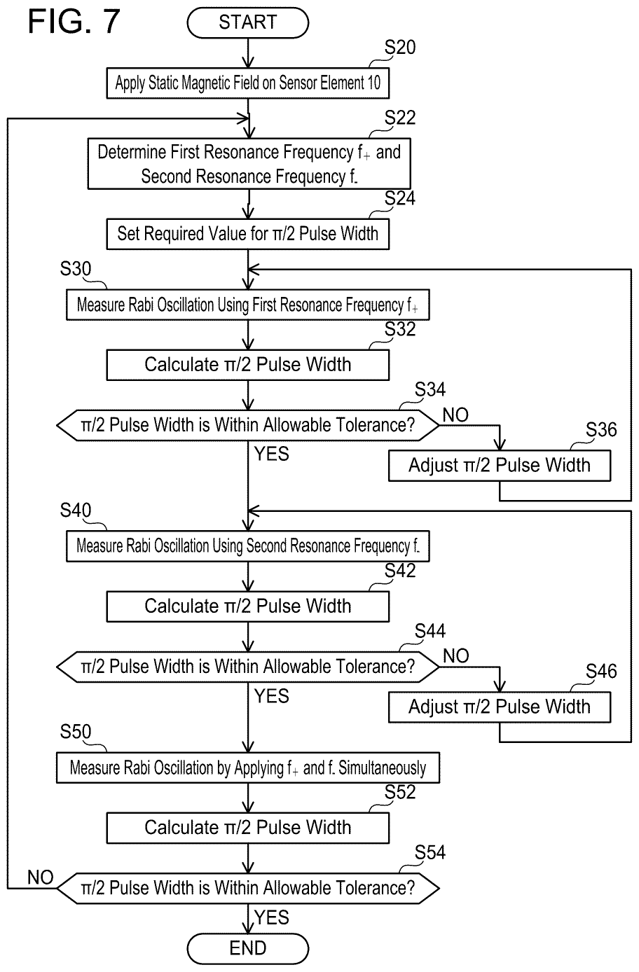

A flow shown in FIG. 7 will be used to describe about the π/2 pulse width calibration performed in step S0 of FIG. 4. In step S20, a static magnetic field is applied to the sensor element 10 using the static magnetic field application unit 50. A generally known static magnetic field may be used.

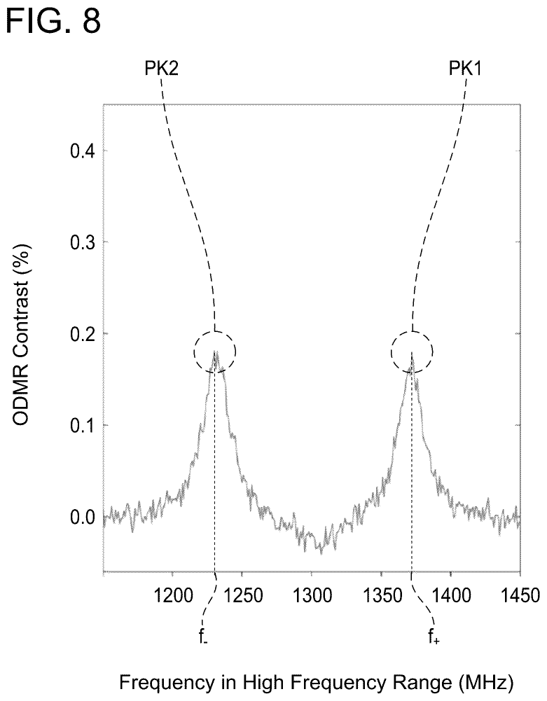

In step S22, the first resonance frequency f₊ and the second resonance frequency f₋ are determined. This determination can be made using a continuous wave ODMR spectrum. FIG. 8 shows an example of the continuous wave ODMR spectrum. A horizontal axis is the frequency in a high frequency range. A vertical axis is an ODMR contrast (percentage change in the emission intensity). The continuous wave ODMR spectrum can be obtained by applying excitation light and high frequency wave as a continuous wave and measuring the emission intensity change that occurs when the frequency of the high frequency wave is changed. Peaks PK1 and PK2 appear at each of the first resonance frequency f₊ and the second resonance frequency f₋. Due to this, the first resonance frequency f₊ and the second resonance frequency f₋ can be determined.

In step S24, a required value (target value) of the π/2 pulse width is set. A constant value may be used as the π/2 pulse width if the π/2 pulse is a constant value that is set due to the device configuration of the physical quantity detection device 1.

In steps S30 to S36, the π/2 pulse width is calibrated by using only the first resonance frequency f₊. This will be described more specifically. In step S30, Rabi oscillation is measured at an arbitrary amplitude of the first resonant frequency f₊. The Rabi oscillation is an oscillation at a constant frequency, as seen when emission intensity (probability of quantum state occupation) is plotted as a function of pulse length.

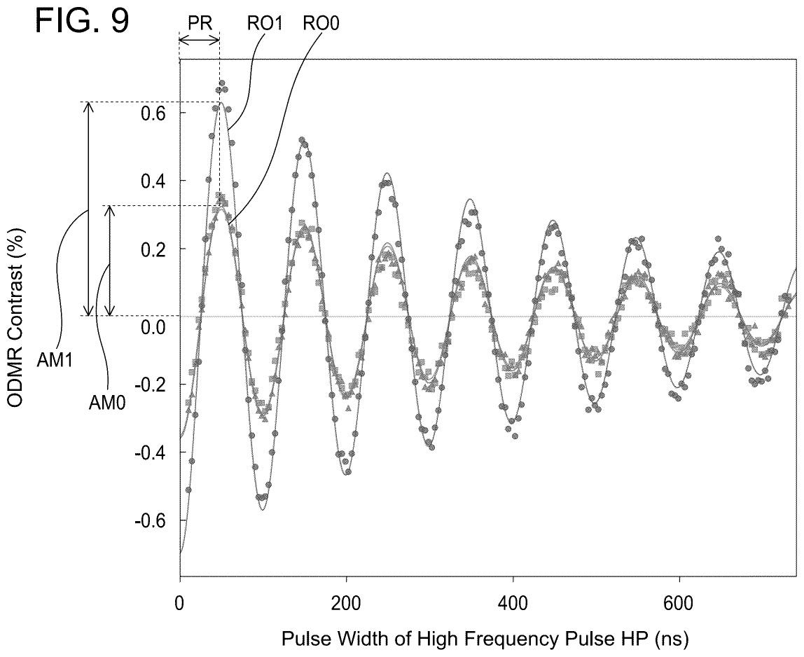

FIG. 9 shows an example of Rabi oscillation. A horizontal axis is the pulse width of the high frequency pulse HP. A vertical axis is the rate of change of the ODMR contrast (emission intensity). In FIG. 9, the plots for the case of using only the first resonance frequency f₊ are shown in triangles. The plots for the case of using only the second resonance frequency f₋ are shown in squares. The plots for the case of using both the first resonance frequency f₊ and the second resonance frequency f₋ simultaneously are shown as circles. Further, the graphs of the Rabi oscillations when only the first resonant frequency f₊ is used and when only the second resonant frequency f₋ is used are shown as a Rabi oscillation RO0. The graph of the Rabi oscillation when the first resonant frequency f₊ and the second resonant frequency f₋ are used simultaneously is shown as a Rabi oscillation RO1.

In this illustrative example, only the first resonance frequency f₊ is used, so the Rabi oscillation RO0 is measured in step S30.

In step S32, the π/2 pulse width is calculated. This will be described more specifically. A Rabi frequency is calculated from the Rabi oscillation measured in step S30. For this calculation, for example, fitting (e.g., fitting using the least-squares method) or FFT can be used. The π/2 pulse width is 1/4 cycle of the calculated Rabi oscillation cycle. In the example of FIG. 9, 1/4 cycle PR is the π/2 pulse width.

In step S34, it is determined whether the calculated π/2 pulse width is within an allowable tolerance. The tolerance may be preset. If the determination is negative (S34: NO), the process proceeds to step S36 to perform feedback adjustment on the π/2 pulse width. This will be described more specifically. The π/2 pulse width of the first resonance frequency f₊ has the property of becoming smaller when the power (amplitude) of the first high frequency signal source 31 increases. Due to this, when the calculated π/2 pulse width is large, the power of the first high frequency signal source 31 can be increased. On the other hand, if the calculated π/2 pulse width is small, the power of the first high frequency signal source 31 can be reduced. Then, the process returns to step S30, and the calculation process of the π/2 pulse width is performed again.

On the other hand, if the calculated π/2 pulse width is within the tolerance in step S34 (S34: YES), the calibration of the π/2 pulse width using only the first resonance frequency f₊ is completed. Therefore, the process proceeds to step S40.

In steps S40 to S46, only the second resonance frequency f₋ is used to calibrate the π/2 pulse width. The respective contents of steps S40 to S46 are the same as those of steps S30 to S36 described above, thus the detailed description will be omitted.

When the calibration of the π/2 pulse width using only the second resonance frequency f₋ is completed, the process proceeds to step S50. In step S50, the first resonance frequency f₊ and the second resonance frequency f₋ are applied simultaneously to measure the Rabi oscillation. The process in step S50 is the same as in step S30 described above. As a result, the Rabi oscillation RO1 is measured, as shown in the example in FIG. 9.

In step S52, the π/2 pulse width is calculated. The processing in step S52 is the same as in step S32 described above. In step S54, it is determined whether the calculated π/2 pulse width is within the tolerance range or not. If the determination is negative (S54: NO), the process returns to step S22 and the calibration is restarted from the beginning. On the other hand, if a positive determination is made (S54: YES), it can be confirmed that the same π/2 pulse width is realized at the first resonance frequency f₊ and the second resonance frequency f₋. Therefore, the calibration process is completed.

The effect of the calibration of the π/2 pulse width is described below. The technique in this embodiment features the simultaneous application of the π/2 pulse of the first resonance frequency f₊ and the π/2 pulse of the second resonance frequency f₋. Therefore, it is important that the π/2 pulse width of the first resonance frequency f₊ and the π/2 pulse width of the second resonance frequency f₋ are the same. However, the π/2 pulse width may vary due to changes in the equipment environment. Further, the π/2 pulse width depends on the power (amplitude) of the first and second high frequency signal sources 31 and 32. In other words, the higher the power of the high frequency signal source, the smaller the π/2 pulse width becomes. Therefore, the π/2 pulse width can be calibrated by feedback controlling the power of the high frequency signal sources based on the calculation result of the π/2 pulse width. This makes it possible to perform operations on two sets of the + qubit QB1 and the − qubit QB2 simultaneously.

### Effects and Principles

In FIG. 9, the Rabi oscillation RO0 in the case of using only the first resonance frequency f₊ and case of using the second resonance frequency f₋ has an amplitude AM0. On the other hand, the Rabi oscillation RO1 for the case where the first resonant frequency f₊ and the second resonant frequency f₋ are applied simultaneously has an amplitude AM1. The amplitude AM1 is about twice the amplitude AM0. Due to this, it can be understood that the detection sensitivity (magnetic sensitivity) of the physical quantity detection device 1 can be substantially doubled in the case where the first resonance frequency f₊ and the second resonance frequency f₋ are applied simultaneously, as compared to the case where only the first resonance frequency f₊ is applied or the case where the second resonance frequency f₋ is applied.

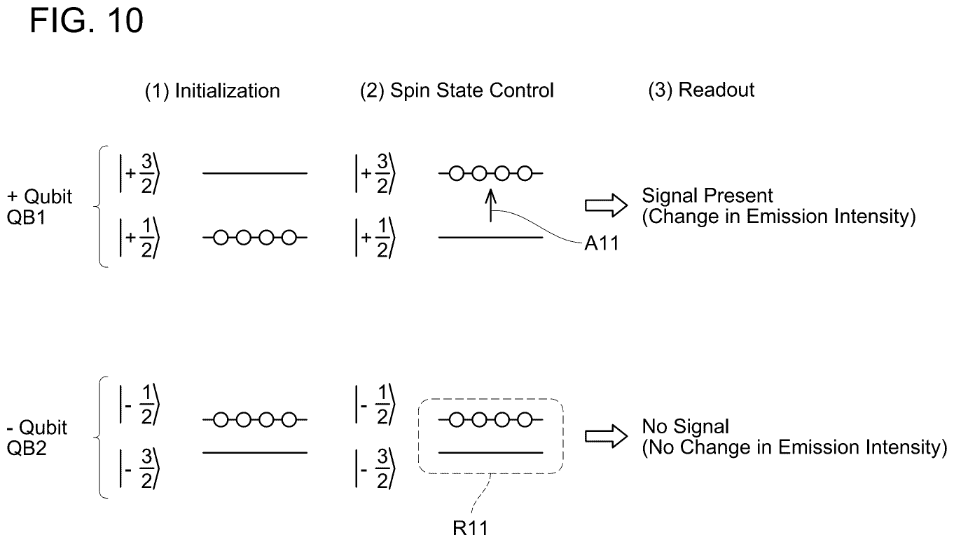

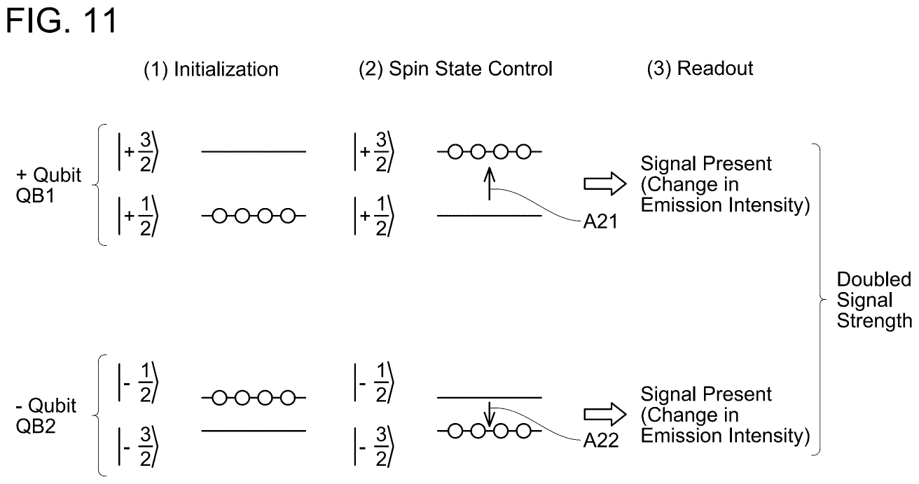

The principle by which the detection sensitivity can be increased will be described using FIGS. 10 and 11. FIG. 10 is a comparative example (using only the first resonance frequency f₊). FIG. 11 is the present embodiment (using the first resonance frequency f₊ and the second resonance frequency f₋ simultaneously). In FIGS. 10 and 11, three states are shown schematically: (1) initialization, (2) spin state control, and (3) readout.

A comparative example is shown in FIG. 10. (1) For initialization, the excitation light pulse is given (see step S1). This initializes the silicon vacancy to a state where m=+1/2 and −1/2 are each occupied with half probability.

Next, in (2) spin state control, only the π/2 pulse of the first resonance frequency f₊ is applied (see step S2). Due to this, the + qubit QB1 (m=+1/2, +3/2) generates a superposition state by resonance (see arrow A11). On the other hand, the −qubit QB2 (m=−1/2, −3/2) does not resonate, and thus remains initialized (see region R11).

(3) During the readout (see step S6), with the + qubit QB1, a change in the light emission intensity is detected and a sensor signal can be obtained. On the other hand, the − qubit QB2 does not contribute to the sensor signal, because it only emits background light without any change in the light emission intensity. That is, the −qubit QB2 is a background noise source.

The present embodiment in FIG. 11 will be described. (1) Initialization is the same as that in the comparative example. (2) In the spin state control, the π/2 pulse of the first resonance frequency f₊ and the π/2 pulse of the second resonance frequency f₋ are applied simultaneously. Due to this, the equivalent + qubit QB1 and − qubit QB2 can be controlled simultaneously. Thus, a superposition state is generated in both the + qubit QB1 and the − qubit QB2 (see arrows A21 and A22). Therefore, (3) since the emission intensity changes in both the + qubit QB1 and the − qubit QB2 at the time of readout, the sensor signals can be acquired from both qubits. Due to this, up to twice the sensor sensitivity can be achieved in the present embodiment as compared to the comparative example.

### Second Embodiment

A second embodiment describes a case in which the physical quantity detected by the physical quantity detection device 1 is a temperature or an electric field. Hereinbelow, only the details specific to the second embodiment will be described.

### (Sequence of Physical Quantity Detection)

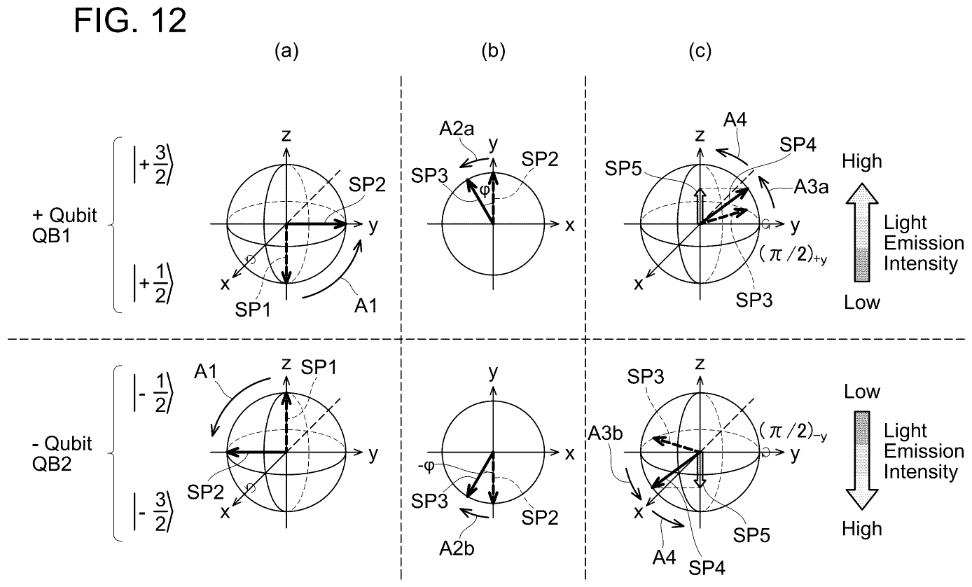

FIG. 12 shows quantum states of the second embodiment. FIG. 12 is similar to FIG. 6 above, where the quantum states are represented by Bloch spheres. The contents of steps S0 to S2 in FIG. 4 are the same for the first and second embodiments. Thus, a state in FIG. 12(a) in second embodiment is identical to the state in FIG. 6(a) of the first embodiment.

In step S3, the information on the physical quantity (temperature or electric field) is accumulated in the phase difference of the quantum states. When the measurement object is a magnetic field (first embodiment, FIG. 6), the sign of the phase φ is identical between the + qubit QB1 and the − qubit QB2. Therefore, both electron spins SP3 rotate counterclockwise (see FIG. 6(b), arrow A2). In contrast, when the measurement target is a temperature or an electric field (second embodiment, FIG. 12), the signs of phase φ are opposite to each other between the + qubit QB1 and the − qubit QB2. Therefore, the electron spin SP3 rotates counterclockwise in the + qubit QB1 (see arrow A2a). On the other hand, in the − qubit QB2, it rotates clockwise (see arrow A2b).

In step S4, the second π/2 pulse irradiation is performed. At this time, the phase of the π/2 pulse of the first resonance frequency f₊ and the phase of the π/2 pulse of the second resonance frequency f₋ are set opposite to each other. Due to this, the direction of rotation of the quantum state about the y-axis can be made opposite to each other between the + qubit QB1 and the − qubit QB2. Specifically, in the + qubit QB1, by rotating the quantum state 90 degrees in the direction of positive rotation of the y-axis, the z-axis component of electron spin SP4 becomes positive (emission intensity increases) (see FIG. 12(c), arrow A3a). On the other hand, in the −qubit QB2, by rotating the quantum state by 90 degrees in the direction of negative rotation of the y-axis, the z-axis component of electron spin SP4 becomes negative (emission intensity becomes larger) (see FIG. 12(c), arrow A3b).

That is, when the measurement target is a temperature or an electric field, if the quantum state is rotated 90 degrees in the direction of positive rotation of the y-axis for both the + qubit QB1 and the − qubit QB2, the z-axis component of the electron spin SP4 of the − qubit QB2 becomes positive (the emission intensity becomes smaller). As a result, the detection signals cancel each other out. To address this, the art disclosed herein configures the direction of rotation of the quantum state about the y-axis inverted between the +qubit QB1 and the −qubit QB2 (i.e., the phase of the π/2 pulse of the first resonance frequency f₊ and the phase of the π/2 pulse of the second resonance frequency f₋ are inverted). Due to this, the emission intensity can be increased for both the + qubit QB1 and the − qubit QB2, by which the sensor sensitivity can be increased as described below.

### (Reason why the Signs of Phase φ are Inverted)

As mentioned above, when the measurement target is a magnetic field (first embodiment, FIG. 6), the sign of the phase φ is identical between the + qubit QB1 and − qubit QB2 (see FIG. 6(b), arrow A2). On the other hand, when the measurement target is a temperature or an electric field (second embodiment, FIG. 12), the signs of phase φ are opposite each other between the +qubit QB1 and − qubit QB2 (see FIG. 12(b), arrows A2a and A2b). The reason for this is explained below.

When the measurement object is a magnetic field, the sign of the phase φ is the same for the + qubit QB1 and the − qubit QB2, as shown in equation (1) below.

$${ϕ}_{+} = {ϕ}_{-} = \vert γ \vert \int δ {B}_{z} ( t ) dt \qquad equation ( 1 )$$

   |γ|: gyromagnetic ratio, δB_{z}(t): minute displacements of B_{z}

This is due to the fact that the resonance frequency (energy level difference) of a qubit is expressed by the following equations (2) and (3).

$${hf}_{+} = h {ω}_{+} = \vert γ \vert {B}_{z} + 2 D \qquad equation ( 2 )$$

$${hf}_{-} = h {ω}_{-} = \vert γ \vert {B}_{z} - 2 D \qquad equation ( 3 )$$

h: Planck's constant, ℏ: Dirac's constant, D: zero-field splitting constant

φ₊ is obtained by time integrating the minute displacements of ω₊, thus results in the above expression.

In the equations (2) and (3) above, the first term including B_{Z} means that the electron spins act as a magnetic field sensor. Further, the sign of the first term is the same for the + qubit QB1 and the −qubit QB2. Therefore, when the measurement object is a magnetic field, the sign of the phase φ is identical (see FIG. 6(b), arrow A2).

On the other hand, when the measurement object is a temperature or an electric field, the energy level difference of a qubit is expressed by the following equations (4) and (5).

$${hf}_{+} = h {ω}_{+} = \vert γ \vert {B}_{z} + 2 D ( T ) + 2 {dE}_{z} \qquad equation ( 4 )$$

$${hf}_{-} = h {ω}_{-} = \vert γ \vert {B}_{z} - 2 D ( T ) - 2 {dE}_{z} \qquad equation ( 5 )$$

d: Constant expressing the strength of the electric dipole interaction

Equations (4) and (5) above are essentially the same as Equations (2) and (3) above. However, the equations (4) and (5) above specify that the zero-field splitting constant number D depends on the temperature T, and further add a new third term for the z-directional electric field E_{Z}, with respect to equations (2) and (3).

The second term, represented by “2D(T),” means that the electron spins act as a temperature sensor. Further, the sign of the second term is inverted between the above equation (4) and equation (5). As such, the phases φ obtained by integrating these small displacements also have signs opposite to each other (see FIG. 12(b), arrows A2a and A2b).

The third term expressed as “2dE_{Z}” means that the electron spins act as an electric field sensor. Further, the sign of the third term is inverted between the above equations (4) and (5). Therefore, the phases φ obtained by integrating these small displacements also have signs opposite to each other (see FIG. 12(b), arrows A2a and A2b).

### Third Embodiment

A third embodiment describes a case where the physical quantity detected by the physical quantity detection device 1 is a physical quantity that undergoes change over time (AC magnetic field AF). In the following, only the details specific to the third embodiment will be described.

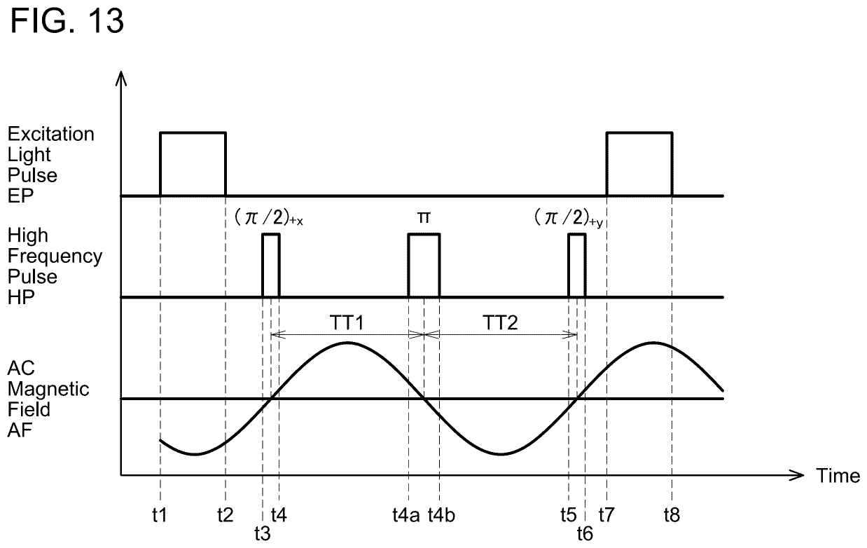

FIG. 13 shows a timing chart for applications of excitation light pulse EP and high frequency pulse HP in the third embodiment. The third embodiment is an example using the spin echo method (also called the Hahn echo method) in magnetic resonance. The timing chart of third embodiment (FIG. 13) differs from the timing chart of first embodiment (FIG. 5) in that a π pulse (time t4a to t4b) is added. Since the details of the spin echo method are well known, a detailed explanation will be omitted.

At time t3 to t4, the first π/2 pulse irradiation is performed. After a predetermined time TT1 elapses, a π pulse irradiation is performed (see time t4a to t4b). The π pulse is a high frequency pulse with twice the length (or twice the amplitude) of the π/2 pulse. The π pulse irradiation can be used to invert (rotate 180 degrees about the x-axis) the electron spins that have accumulated in phase due to the interaction with the measurement target in the plane. Further, after a predetermined time TT2 elapses from the π pulse irradiation, the second π/2 pulse irradiation is performed (see time t5 to t6). The predetermined times TT1 and TT2 are times corresponding to a half cycle of the AC magnetic field AF to be measured.

The spin-echo method can be used to counteract the effects of static disturbances added to the quantum state. Here, the static disturbances are effects such as external fields that change in time sufficiently slowly compared to the length of the DC or this sequence. This will be described more specifically. During the predetermined time TT1, the static disturbance causes an accumulation of phase φ (the tip position of the electron spin rotates by phase φ in the xy-plane). Then, when the predetermined time TT1 elapses, inversion by a π pulse is performed. During the subsequent predetermined time TT2, an accumulation of phase φ occurs due to the static disturbance, but because of the inversion, the phases φ cancel out each other. That is, regardless of the magnitude of the disturbance (i.e., the magnitude of phases φ), the disturbance component (static magnetic field component) is cancelled out, so the disturbance has no effect on the quantum states.

On the other hand, in the AC magnetic field AF synchronized with a pulse train, the sign of the phase accumulation after the inversion by the π pulse changes to −φ. This means that in the AC field AF, a tip position of the electron spin in the xy-plane is rotated by phase 2φ. Therefore, the magnitude of the AC field AF is not canceled out and thus can be read out.

### (Example of AC Magnetic Field AF Measurement Result)

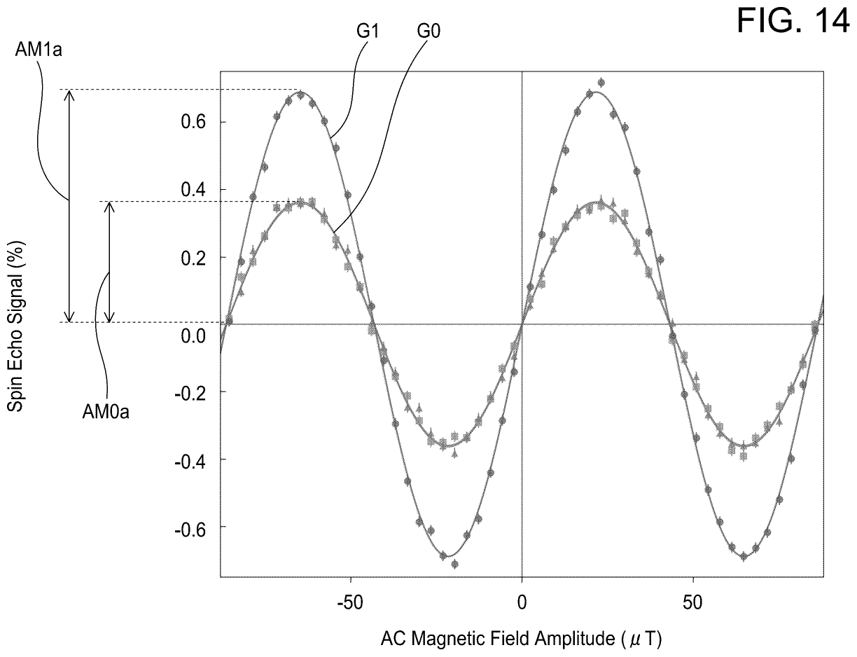

FIG. 14 shows an example of results of a sensor operation with an AC magnetic field AF application. A horizontal axis is an amplitude of the AC magnetic field. A vertical axis is a rate of change of a spin echo signal. In FIG. 14, the plots using only the first resonance frequency f₊ are shown in triangles. The plots using only the second resonance frequency f₋ are shown in squares. The plots using both the first resonance frequency f₊ and the second resonance frequency f₋ simultaneously are shown in circles. Further, the case of using only the first resonance frequency f₊ and the case of using only the second resonance frequency f₋ are shown in a graph G0. A graph for the case where the first resonance frequency f₊ and the second resonance frequency f₋ are used simultaneously is shown in a graph G1.

If the AC magnetic field amplitude is b, the phase accumulation 2φ is expressed by the following equation (6).

$$2 ϕ = γ b / π f \qquad equation ( 6 )$$

γ: Constant called gyromagnetic ratio. f: AC magnetic field frequency

The information to be read is the occupancy probability of the quantum state (z-coordinate of electron spin SP5 in FIG. 6(c)). Therefore, shapes of graphs G0 and G1 are as in equation (7) below.

$$sin ( 2 ϕ ) = sin ( \frac{γ b}{π f} ) \qquad equation ( 7 )$$

In FIG. 14, the graph G0 for the case of using only the first resonance frequency f₊ and the case of using only the second resonance frequency f₋ has an amplitude AM0a. On the other hand, the graph G1 for the case where both the first resonance frequency f₊ and the second resonance frequency f₋ are applied simultaneously has an amplitude AM1a. Further, the amplitude AM1a is about twice the amplitude AM0a. This means that, by simultaneously applying the first resonance frequency f₊ and the second resonance frequency f₋, the detection sensitivity of the physical quantity detection device 1 (AC magnetic field AF sensitivity) can be substantially doubled as compared to the case of applying only the first resonance frequency f₊ or the case of applying only the second resonance frequency f₋.

While specific embodiments of the present invention have been described in detail above, such description is for illustrative purposes only and is not intended to limit the scope and claims of the invention. Techniques described in the claims of the invention include various modifications and changes made to the specific examples illustrated above. Furthermore, it is to be understood that the technical elements described in the present specification and the drawings exhibit technical usefulness solely or in various combinations thereof and shall not be limited to the combinations described in the claims at the time of filing. The techniques illustrated in the present specification and the drawings are to achieve a plurality of objectives at the same time, and technical usefulness is exhibited by attaining any one of such objectives.

### (Variants)

In the above embodiments, the case of using the silicon vacancy in 4H-SiC as the emission center is described, however, no limitation is made to this configuration, and various emission centers can be used. For example, a Frenkel defect in 6H-SiC can be used as the emission center. In this case, the dependence of the second term (D(T)) in the above equations (4) and (5) on T can be increased. This makes it possible to increase the sensitivity of the temperature sensor.

In the above embodiments, SiC was used as the material having the emission center, however, no limitation is made to this configuration. Various materials with color centers, such as diamond, SiC, and hBN, can be used.

The configuration of the high frequency pulse generator 30 is not limited to the configuration shown in FIG. 1, but may be in various other configurations. For example, it may be configured to directly generate the high frequency pulse HP with two frequencies, namely the first resonance frequency f₊ and the second resonance frequency f₋, using an arbitrary waveform generator. Further, it may also be configured to obtain the desired frequency by frequency conversion using a high frequency mixer.

In the π/2 pulse width calibration sequence (FIG. 7), the order of each process may be recombined or one or more processes may be skipped. For example, the order of the calibration process of S30 to S36 and S40 to S46 may be swapped. If the first resonance frequency f₊ and the second resonance frequency f₋ are known, step S22 may be omitted.

Several aspects of the present art will be listed herein below.
[Aspect 1]A physical quantity detection device comprising:
   a sensor element including an emission center;
   an excitation light pulse generator configured to generate excitation light and irradiate the excitation light to the sensor element;
   a high frequency pulse generator configured to generate a high frequency pulse for controlling a spin qubit of the emission center and irradiate the high frequency pulse to the sensor element; and
   a light detector configured to detect light emission from the emission center,
   wherein
   the emission center has two spin qubits that differ from each other,
   the two spin qubits are equivalent to each other and have different levels from each other, and
   the high frequency pulse generator generates the high frequency pulse in which two different frequencies are superimposed and irradiates the high frequency pulse to the sensor element to simultaneously perform control on the two spin qubits.
[Aspect 2] The physical quantity detection device according to aspect 1, wherein
   the emission center has a spin 3/2 that is photo-detectable and magnetic resonance-detectable in silicon carbide.
[Aspect 3] The physical quantity detection device according to aspect 2, wherein
   the two spin qubits are pairs of magnetic quantum numbers {+3/2, +1/2} and {−3/2, −1/2}.
[Aspect 4] The physical quantity detection device according to aspect 3, wherein
   the two frequencies are a first resonance frequency which is a resonance frequency of the magnetic quantum numbers +1/2 and +3/2 and a second resonance frequency which is a resonance frequency of the magnetic quantum numbers −1/2 and −3/2.
[Aspect 5] The physical quantity detection device according to any one of aspects 1 to 4, wherein
   the high frequency pulse generator comprises:
   a first high frequency signal source configured to generate a high frequency signal of the first resonance frequency;
   a second high frequency signal source configured to generate a high frequency signal of the second resonance frequency; and
   a synthesizer configured to generate the high frequency pulse by synthesizing an output from the first high frequency signal source and an output from the second high frequency signal source.
[Aspect 6] The physical quantity detection device according to any one of aspects 1 to 5, further comprising:
   a controller configured capable of controlling operations of the excitation light pulse generator, the high frequency pulse generator, and the light detector,
   wherein the controller is configured to:
   cause the excitation light pulse generator to perform a first excitation light irradiation of irradiating the sensor element with an excitation light pulse;
   cause the high frequency pulse generator to perform a first π/2 pulse irradiation of irradiating the sensor element with a π/2 pulse of the high frequency pulse;
   cause the high frequency pulse generator to perform a second π/2 pulse irradiation of irradiating the sensor element with the π/2 pulse of the high frequency pulse after a predetermined time has elapsed from the first π/2 pulse irradiation;
   cause the excitation light pulse generator to perform a second excitation light irradiation of irradiating the sensor element with the excitation light pulse after having performed the second π/2 pulse irradiation; and
   cause the light detector to detect a light emission state of the emission center resulting from the second excitation light irradiation.
[Aspect 7] The physical quantity detection device according to aspect 6, wherein
   the two spin qubits are pairs of magnetic quantum numbers {+3/2, +1/2} and {−3/2, −1/2},
   the two frequencies are a first resonance frequency which is a resonance frequency of the magnetic quantum numbers +1/2 and +3/2 and a second resonance frequency which is a resonance frequency of the magnetic quantum numbers −1/2 and −3/2, and
   one of a pulse phase of the first resonance frequency and a pulse phase of the second resonance frequency included in the high frequency pulse used in the second π/2 pulse irradiation is inverted relative to a pulse phase of the first resonance frequency and a pulse phase of the second resonance frequency in the high frequency pulse used in the first π/2 pulse irradiation.
[Aspect 8] The physical quantity detection device according to aspect 6 or 7, wherein
   a physical quantity detected by the physical quantity detection device is a temperature or an electric field.
[Aspect 9] A method of controlling a physical quantity detection device that comprises:
   a sensor element including an emission center;
   an excitation light pulse generator configured to generate excitation light and irradiate the excitation light to the sensor element;
   a high frequency pulse generator configured to generate a high frequency pulse for controlling a spin qubit of the emission center and irradiate the high frequency pulse to the sensor element; and
   a light detector configured to detect light emission from the emission center,
   wherein
   the emission center has two spin qubits that differ from each other, and
   the two spin qubits are equivalent to each other and have different levels from each other,
   the method comprising:
   generating, using the high frequency pulse generator, the high frequency pulse in which two different frequencies are superimposed; and
   irradiating the generated high frequency pulse to the sensor element to simultaneously perform control on the two spin qubits.
[Aspect 10]A computer-readable recording medium storing instructions for controlling a physical quantity detection device that comprises:
   a sensor element including an emission center;
   an excitation light pulse generator configured to generate excitation light and irradiate the excitation light to the sensor element;
   a high frequency pulse generator configured to generate a high frequency pulse for controlling a spin qubit of the emission center and irradiate the high frequency pulse to the sensor element;
   a light detector configured to detect light emission from the emission center;
   a memory; and
   an arithmetic circuit,
   wherein
   the emission center has two spin qubits that differ from each other, and
   the two spin qubits are equivalent to each other and have different levels from each other,
   when executed by the arithmetic circuit, the instructions cause the arithmetic circuit to function as:
   a generation unit configured to generate, using the high frequency pulse generator, the high frequency pulse in which two different frequencies are superimposed; and
   an irradiation unit configured to irradiate the high frequency pulse to the sensor element to simultaneously perform control on the two spin qubits.

What is claimed is:

1. A physical quantity detection device comprising:
a sensor element including an emission center;
an excitation light pulse generator configured to generate excitation light and irradiate the excitation light to the sensor element;
a high frequency pulse generator configured to generate a high frequency pulse for controlling a spin qubit of the emission center and irradiate the high frequency pulse to the sensor element; and
a light detector configured to detect light emission from the emission center,
wherein
the emission center has two spin qubits that differ from each other,
the two spin qubits are equivalent to each other and have different levels from each other, and
the high frequency pulse generator generates the high frequency pulse in which two different frequencies are superimposed and irradiates the high frequency pulse to the sensor element to simultaneously perform control on the two spin qubits.

2. The physical quantity detection device according to claim 1, wherein
the emission center has a spin 3/2 that is photo-detectable and magnetic resonance-detectable in silicon carbide.

3. The physical quantity detection device according to claim 2, wherein
the two spin qubits are pairs of magnetic quantum numbers {+3/2, +1/2} and {−3/2, −1/2}.

4. The physical quantity detection device according to claim 3, wherein
the two frequencies are a first resonance frequency which is a resonance frequency of the magnetic quantum numbers +1/2 and +3/2 and a second resonance frequency which is a resonance frequency of the magnetic quantum numbers −1/2 and −3/2.

5. The physical quantity detection device according to claim 4, wherein
the high frequency pulse generator comprises:
a first high frequency signal source configured to generate a high frequency signal of the first resonance frequency;
a second high frequency signal source configured to generate a high frequency signal of the second resonance frequency; and
a synthesizer configured to generate the high frequency pulse by synthesizing an output from the first high frequency signal source and an output from the second high frequency signal source.

6. The physical quantity detection device according to claim 1, further comprising:
a controller configured capable of controlling operations of the excitation light pulse generator, the high frequency pulse generator, and the light detector,
wherein the controller is configured to:
cause the excitation light pulse generator to perform a first excitation light irradiation of irradiating the sensor element with an excitation light pulse;
cause the high frequency pulse generator to perform a first π/2 pulse irradiation of irradiating the sensor element with a π/2 pulse of the high frequency pulse;
cause the high frequency pulse generator to perform a second π/2 pulse irradiation of irradiating the sensor element with the π/2 pulse of the high frequency pulse after a predetermined time has elapsed from the first π/2 pulse irradiation;
cause the excitation light pulse generator to perform a second excitation light irradiation of irradiating the sensor element with the excitation light pulse after having performed the second π/2 pulse irradiation; and
cause the light detector to detect a light emission state of the emission center resulting from the second excitation light irradiation.

7. The physical quantity detection device according to claim 6, wherein
the two spin qubits are pairs of magnetic quantum numbers {+3/2, +1/2} and {−3/2, −1/2},
the two frequencies are a first resonance frequency which is a resonance frequency of the magnetic quantum numbers +1/2 and +3/2 and a second resonance frequency which is a resonance frequency of the magnetic quantum numbers −1/2 and −3/2, and
one of a pulse phase of the first resonance frequency and a pulse phase of the second resonance frequency included in the high frequency pulse used in the second π/2 pulse irradiation is inverted relative to a pulse phase of the first resonance frequency and a pulse phase of the second resonance frequency in the high frequency pulse used in the first π/2 pulse irradiation.

8. The physical quantity detection device according to claim 7, wherein
a physical quantity detected by the physical quantity detection device is a temperature or an electric field.

9. A method of controlling a physical quantity detection device that comprises:
a sensor element including an emission center;
an excitation light pulse generator configured to generate excitation light and irradiate the excitation light to the sensor element;
a high frequency pulse generator configured to generate a high frequency pulse for controlling a spin qubit of the emission center and irradiate the high frequency pulse to the sensor element; and
a light detector configured to detect light emission from the emission center,
wherein
the emission center has two spin qubits that differ from each other, and
the two spin qubits are equivalent to each other and have different levels from each other,
the method comprising:
generating, using the high frequency pulse generator, the high frequency pulse in which two different frequencies are superimposed; and
irradiating the generated high frequency pulse to the sensor element to simultaneously perform control on the two spin qubits.

10. A computer-readable recording medium storing instructions for controlling a physical quantity detection device that comprises:
a sensor element including an emission center;
an excitation light pulse generator configured to generate excitation light and irradiate the excitation light to the sensor element;
a high frequency pulse generator configured to generate a high frequency pulse for controlling a spin qubit of the emission center and irradiate the high frequency pulse to the sensor element;
a light detector configured to detect light emission from the emission center;
a memory; and
an arithmetic circuit,
wherein
the emission center has two spin qubits that differ from each other, and
the two spin qubits are equivalent to each other and have different levels from each other,
when executed by the arithmetic circuit, the instructions cause the arithmetic circuit to function as:
a generation unit configured to generate, using the high frequency pulse generator, the high frequency pulse in which two different frequencies are superimposed; and
an irradiation unit configured to irradiate the high frequency pulse to the sensor element to simultaneously perform control on the two spin qubits.
